(19) United States
(12) Patent Application Publication
(10) Pub. No.: US 2011/0140738 A1
(43) Pub. Date: Jun. 16, 2011

(54) Multi-Phase Integrators in Control Systems

(75) Inventor: Andrew Martin Mallinson, Kelowna (CA)

(73) Assignee: ESS Technology, Inc., Fremont, CA (US)

(21) Appl. No.: 12/683,162

(22) Filed: Jan. 6, 2010

Related U.S. Application Data
(63) Continuation of application No. PCT/US10/20154, filed on Jan. 5, 2010.
(60) Provisional application No. 61/285,893, filed on Dec. 11, 2009.
(60) Provisional application No. 61/285,893, filed on Dec. 11, 2009.

(51) Int. Cl. G05B 6/02; H03L 7/085; G05B 13/02

(52) U.S. Cl. 327/16; 331/17; 700/28

(57) ABSTRACT

Multi-phase integrators in control systems are described.

### REFERENCE TO RELATED APPLICATION

This application is a continuation of PCT Application No. PCT/US10/20154, filed 5 Jan. 2010 which claims the benefit of U.S. Provisional Application No. 61/285,893 filed 11 Dec. 2009, and this application claims the benefit of U.S. Provisional Application No. 61/285,893 filed 11 Dec. 2009, all of which are incorporated by reference herein.

### SUMMARY OF THE INVENTION

Various embodiments relate to multi-phase integrators in control systems.

One aspect is an apparatus with a control loop. The control loop includes a plurality of integrators connected in parallel and having a collective input range. The collective input range is divided among different input ranges of different integrators of the plurality of integrators.

In some embodiments the control loop includes an aggregator and a control element. The aggregator aggregates outputs of the plurality of integrators. The control element is responsive to the aggregator, and the control element controls the plurality of integrators.

In some embodiments the plurality of integrators are connected in parallel electrically, and the control loop is a phase lock loop. The phase lock loop includes a voltage controlled oscillator and a phase or frequency detector. The voltage controlled oscillator is responsive to the plurality of integrators. The phase or frequency detector is responsive to output of the voltage controlled oscillator. The phase or frequency detector sends a feedback signal toward input of the plurality of integrators.

In one embodiment the voltage controlled oscillator includes a series connected loop of amplifiers and adjustable resistors. In one embodiment the adjustable resistors include a parallel combination of adjustable resistors. In one embodiment the adjustable resistors are controlled by different outputs of the different integrators of the plurality of integrators.

In one embodiment the control loop includes a transconductance element. The transconductance element is responsive to output of the phase or frequency detector. The plurality of integrators are responsive to output of the transconductance element.

In some embodiments the plurality of integrators are connected in parallel electrically, and the control loop is an automatic gain control loop. The automatic gain control loop includes a variable gain amplifier and an amplitude detector. The variable gain amplifier is responsive to a feedback signal from the plurality of integrators. The amplitude detector is responsive to output of the variable gain amplifier. The amplitude detector sends amplitude detector output toward the input of the plurality of integrators.

In one embodiment the variable gain amplifier has a linear transfer characteristic. In another embodiment the variable gain amplifier has a logarithmic transfer characteristic.

In some embodiments differently valued resistances are in series between (i) the different outputs of the different integrators of the plurality of integrators and (ii) the variable gain amplifier.

Some embodiments also include a series of resistances between a high voltage reference and a low voltage reference. Different points along the series of resistances provide different voltage references to noninverting inputs of the different integrators of the plurality of integrators.

Another aspect of the technology is a control loop method. The method includes the step of:
responsive to input voltage received by a plurality of integrators connected in parallel, changing an integrator among the plurality of integrators and such that other integrators in the plurality of integrators are inactive.

Some embodiments includes the step of:
providing different voltage references to noninverting inputs of different integrators in the plurality of integrators.

One embodiment includes the step of:
the plurality of integrators assisting in phase lock loop processing.

One embodiment includes the step of:
different integrators in the plurality of integrators controlling different variable resistances in a voltage controlled oscillator that assists in the phase lock loop processing.

One embodiment includes the step of:
the plurality of integrators assisting in automatic gain control processing.

In one embodiment the automatic gain control processing has a logarithmic transfer characteristic.

### BRIEF DESCRIPTION OF THE DRAWINGS

FIG. 1 shows a circuit diagram of a phase locked loop with a pole and a zero.

FIG. 2 shows a circuit diagram of a phase locked loop where the integrator has a pole and no zero.

FIG. 3 shows a circuit diagram of a phase locked loop with a transconductance element replacing a resistor preceding the integrator.

FIG. 4 shows a circuit diagram of a phase locked loop with multiple integrators connected in parallel.

FIG. 5 shows a circuit diagram of a phase locked loop with multiple integrators connected in parallel having different operating input ranges.

FIG. 6 shows a circuit diagram of a voltage controlled oscillator, such as one shown in FIG. 5.

FIG. 7 shows a circuit diagram of part of a voltage controlled oscillator, such as one shown in FIG. 6, where the variable resistors include parallel variable resistors.

FIG. 8 shows a circuit diagram of part of a voltage controlled oscillator, such as one shown in FIG. 7, where the variable resistors include parallel transistors controlled by different integrators of the parallel connected integrators.

FIG. 9 shows a circuit diagram of an automatic gain control loop.

FIG. 10 shows a linear transfer characteristic of an automatic gain control loop.

FIG. 11 shows a circuit diagram of an automatic gain control loop with multiple integrators connected in parallel having different operating input ranges.

FIG. 12 shows a logarithmic transfer characteristic of an automatic gain control loop.

FIG. 13 shows a circuit diagram of a transconductance element.

### DETAILED DESCRIPTION

In a classical control system, a control creates a signal ‘u’ that adjusts the operation of a plant. A signal ‘y’ from the plant is measured by a feedback element which generates a feedback signal. The feedback signal is subtracted from the requested signal ‘r’ to create an error signal ‘e’. The error is applied to the control. Consequently, a control loop is created.

However, in any implementation of a control loop, in addition to the first order requirement that the loop be stable, artifacts are present due to the imperfect nature of the physical elements. Such artifacts are second order effects and not relevant to loop stability, but concerned with potential imperfection in the loop once stability has been reached.

One such imperfection is instability in the plant due to noise present on the control output. This arises because in any physical implementation the output range of the control is bounded, and these bounds encompass the entire design range of variability of the plant. Noise is present in any physical implementation of the control output, and this translates into a noise-limited variability in the plant.

This technology relates to electronic implementations of a control system and applies to the design of an electronic integrator that commonly acts as the control element of the loop. Such an electronic integrator is formed by use of an op-amp in the virtual ground configuration having a capacitor in the feedback and a resistor in the input.

In practice the voltage applied to the op-amp of the electronic integrator sets the bounds of output: the integrator output may not be higher than the positive power supply or lower than the negative power supply. Noise of various kinds causes the output of an electronic integrator to have a disturbance. Such noise may be thermal noise or induced noise that is generated by close proximity to other electronic elements operating at high speed and undesirably coupling into the op-amp output. Given these two constraints—that the output range is limited and noise is present on the output—the disturbance to the plant when stability is reached is inferred from the upper and lower operating range of the plant.

For example, suppose the loop is a Phase Locked Loop (PLL) designed to operate from 900 MHz to 1100 MHz. Suppose that the integrator is powered from a two volt supply, able to create an output between zero and two volts, and has noise on the output of 1 mV. Given that the loop is stable, the output frequency exhibits at least a 100 kHz variation, as follows. The 1V of integrator output corresponds to 100 MHz of change in frequency—if it did not the 900-1100 MHz range could not be covered—and therefore the 1 mV of noise corresponds to at least 100 kHz of disturbance.

Or, (100 kHz/1 mV)=(100 MHz/1V).

This technology breaks this necessary relation of noise and range of operation of the plant, with a multi-phase integrator and a summation of each integrator output to form the plant control. Many embodiments include one of two further conditions:

(i) the noise of the integrator output is reduced when the limit of operation is reached (for example, in a simple integrator, when the power supply is reached, the signal from the input is cut off, so the noise contribution of the input pair of devices is removed, and any induced noise on the input is removed. Power supply noise however remains.), and

(ii) the summation of individual outputs is non-linear and of decreasing sensitivity as the limit of each individual plant control input is reached. For example, in a voltage controlled oscillator (VCO) which is the ‘plant’ of the PLL, the summation of multi-phase inputs may virtually arise from the effective control resistance. Specifically, each individual integrator output may control the gate of a device operating as a variable resistance. When the control reaches one extreme the device is off—a very high resistance—at the other extreme the device is fully on and no more reduction in resistance can be achieved. Therefore, the noise on the control signals at these extremes is negligible: no change in resistance is created by a noise on the control. This therefore achieves two things: the addition of the multi-phase integrator output occurs with the controlled element (the total resistance) and there is a decreased sensitivity to noise at the limits.

Furthermore, various embodiments employ new ability: since the plant control is the sum of the multi-phase integrator outputs, that sum may be weighted. Some embodiments have a piece-wise linear interpolated characteristic that corrects a known nonlinearity of plant control, or introduce a desirable non-linearity of plant control. For example, if the loop is an Automatic Gain Control (AGC) system the ideal characteristic of the gain control element is logarithmic. See for example “On the Design of Constant Settling Time AGC Circuits”, John M. Khoury, IEEE transactions on circuits and systems, vol. 45, no. 3, March 1998, incorporated by reference herein. In this case, an arbitrary monotonically increasing plant response to the control may be made to approximate exponential response by piece-wise linear interpolation.

Example with a Phase Locked Loop

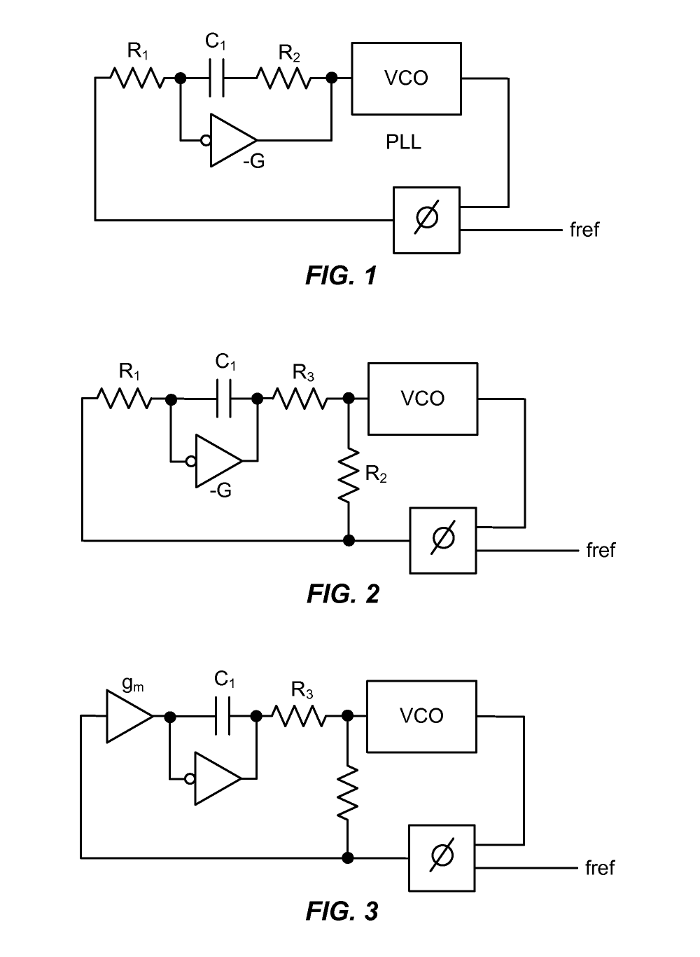

FIG. 1 shows a Phase Locked Loop. There is an integrator, and a zero in the loop characteristic is provided by R2. The loop pole is set by R1.C, and the zero by R2.C. PLL is an example of an inherently second order system. The phase being the integral of frequency creates one pole and the loop stability requires that only one pole is present in the response, hence the zero in the explicit integrator as shown here.

The voltage controlled oscillator (VCO) accepts a control input voltage on its left input and creates a clock output of variable frequency on its right output. The element Φ is the frequency/phase detector. The element ‘−G’ is a virtual ground configured op-amp—the node marked with the “bubble” is the virtual ground and consequently current flowing through R1 is accumulated on C1. The output is the integral of the current due to C1 plus the instantaneous value of the current due to R2. Hence a pole and a zero are created.

FIG. 2 shows how the zero is created by adding the direct phase detector output to the now single pole (no zero) integrator using R3 and the R2. The signal at the VCO input is now R2∥R3.(Vp/R2+Vi/R3) where ∥ is the parallel operator, Vp is the phase detector output and Vi is the integrator output. Scaling R3 and R2 moves the zero position.

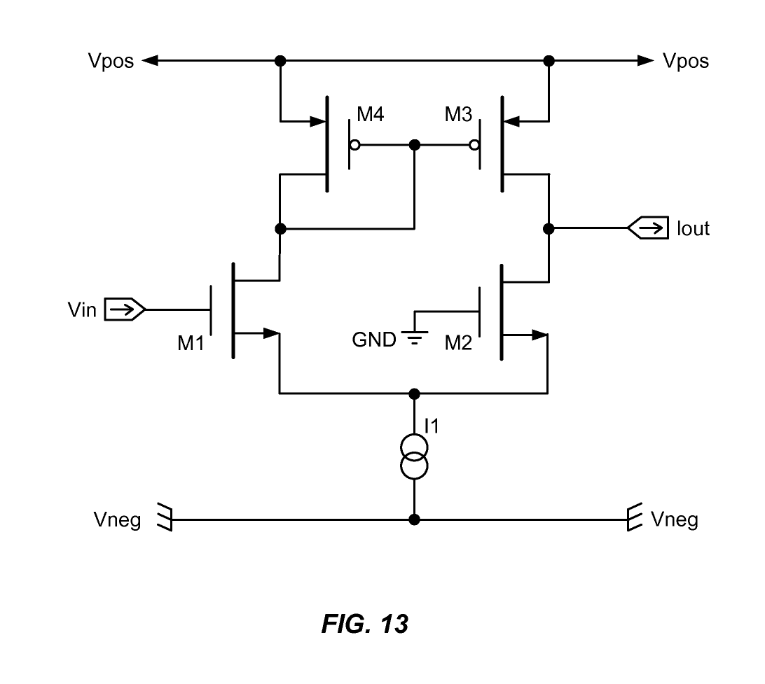

FIG. 3 shows that the resistor is replaced with a transconductance element ‘gm’ and, assuming gm=1/R1 there is no change to the loop. Examples of the gm element are a voltage to current converter. For example, a single FET device and load network functions. In another example, the input stage of an op-amp operates as a gm device. An example is shown in FIG. 13.

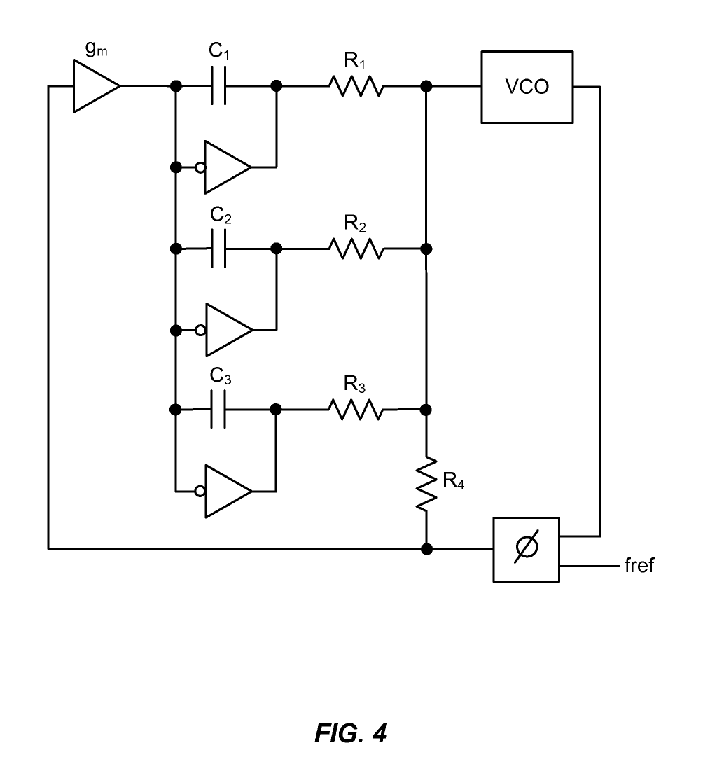

FIG. 4 shows the technology with multiple instances of the integrator. The output is summed by R1-R4. The sum of three integrator outputs and the zero feed-forward signal are applied to the VCO input. FIG. 4 lacks the aspect of the integrators operating in succession, since all are connected in parallel.

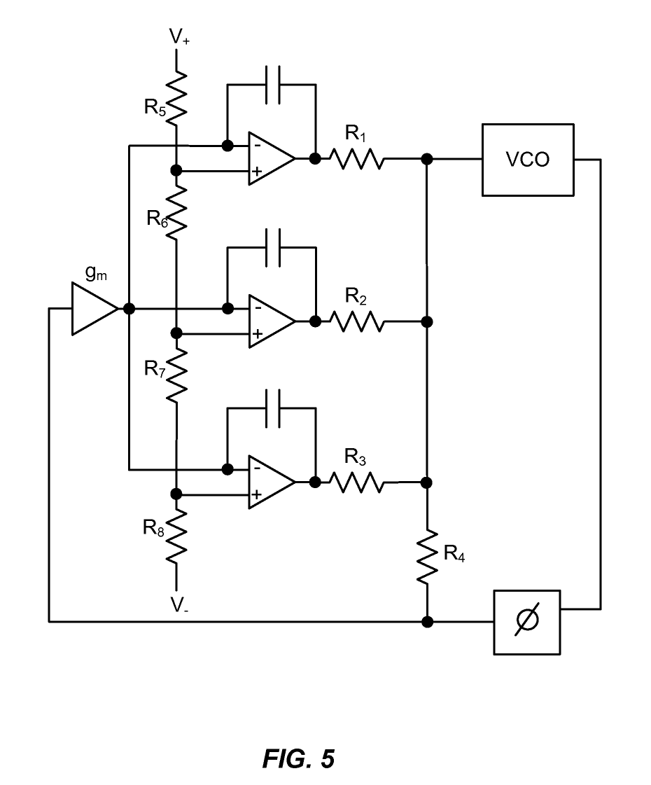

The operations of the integrators are made to be successive by the presence of a deliberate offset in the nominally ground input as shown in FIG. 5. V+ and V− are such that the upper integrator has +10 mV on its positive input, the center integrator has 0V on its positive input, and the lower integrator has −10 mV on its positive input. Also, the power supply to each integrator is such that the output may go between −1V and +1V.

In these conditions only one integrator can be active at any time. If the input voltage to the integrators (that is the output voltage of the ‘gm’ circuit) is near to 0V, then the center integrator provides a signal back and forth from its output though the associated capacitor as long as that output remains within +/−1V. But since this center integrator is assumed to be active holding its virtual ground to zero volts, the upper integrator cannot be active: it sees +10 mV at its positive input, hence its output is at the upper limit, at +1V. Similarly the lower integrator cannot be active: its input is −10 mV and so its output is at the lower limit, at −1V.

As the control loop operates to drive the center integrator higher, it eventually reaches its limit of +1V and so loses control of its virtual ground. Consequently the integrator input starts to drift downward (the center integrator can no longer prevent this since its output is clipped high). This moves the input nearer the threshold of the lower integrator, and it starts to operate to maintain its virtual ground, which is −10 mV. Consequently the loop control now moves to the output of the lower integrator and it takes control. The successive action of the integrators is achieved by a deliberate offset in the virtual ground points. Once having lost control the input moves to the next integrator in turn.

Although the discussed embodiment has evenly separated virtual ground voltages, other embodiments have unevenly separated virtual ground voltages, or a mix of evenly separated virtual ground voltages and unevenly separated virtual ground voltages.

The substitution of the ‘g’ element for the input resistor is beneficial, because it operates independently of the integrator input voltage. With a resistor there is a small error due to the supposedly virtual ground point moving. The virtual ground moves as each integrator takes over in turn.

If the PLL is designed to operate from 900 MHz to 1100 MHz on a low power supply—as is desirable in modern battery powered devices—then the input voltage range of at most −1V to +1V in this example corresponds to a transfer characteristic of 100 MHz per volt. 1 mV of noise creates 100 kHz of deviation from the ideal frequency.

This example uses an integrator with an output noise of 1 mV. This output noise is due to a variety of factors: input thermal noise, induced spurious noise, etc. That single integrator output connects to the VCO input un-attenuated, hence creating 100 kHz of deviation due to noise. But in one embodiment with 32 integrators, only one of the 32 is active, and its output is attenuated by 1/32 at the VCO input. Hence the noise is 32× less, or about 3 kHz of deviation, not 100 kHz. This is a significant improvement in frequency noise.

Each of the other 31 integrators is also making noise. And, to the extent that this noise is correlated it will not be reduced, since all are still adding with 1/32 weight to the VCO input. Thermal noise is uncorrelated and hence is reduced by 1/(square root of 32), but induced noise may well be correlated and so not reduced at all. But these other integrators are making far less noise than the active one. Their input stages are shut off since at least 10 mV is applied to the input pushing them out of the linear region. Those further from the active one have even greater input offset, driving them into saturation which is a lower noise state than the active state. Consequently, even without further modification to the PLL architecture, lower noise is available with this technology.

The more integrators that are used, the more beneficial the effect. Therefore, in some embodiments, a typical implementation may use as many as 24 integrators or 32 integrators.

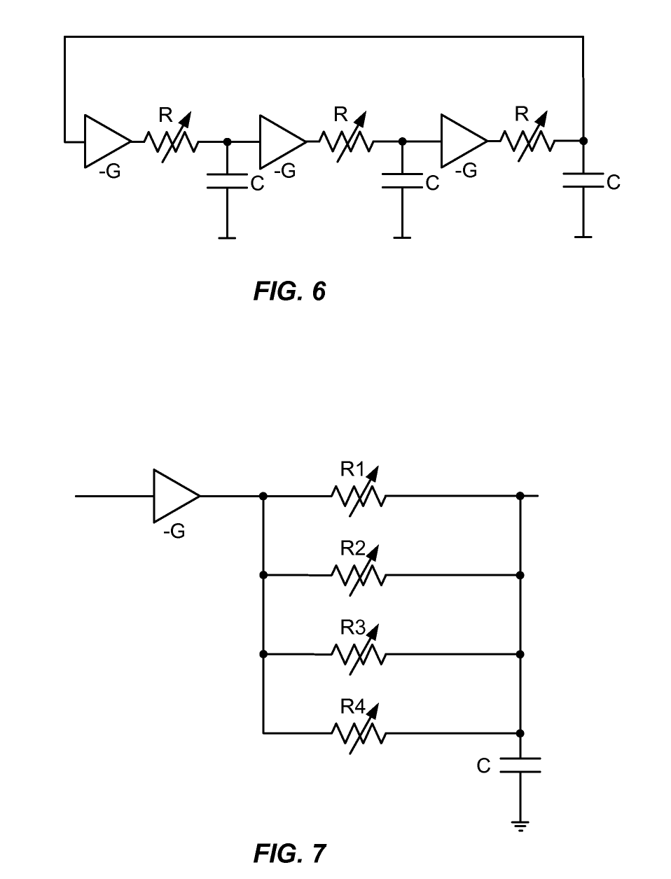

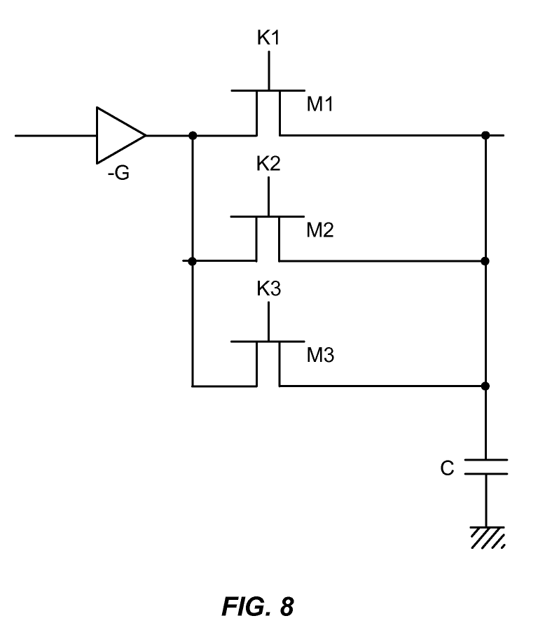

However, some embodiments further reduce the noise. The VCO, such as the VCO shown in FIG. 5, is constructed as follows. FIGS. 6-8 show details of the VCO of 5; and specifically how a phase shift oscillator can by made with an R (resistor) in many parts, each of which may be controlled by separate outputs from the multiple integrator. FIG. 6 is a three element “phase shift” oscillator, the frequency being determined by the resistor and capacitor values. As each R is adjusted (all together) the frequency of oscillation changes. FIG. 7 shows how the single adjustable resistor is made with a combination of resistors. FIG. 8 shows how a single FET implements each adjustable resistor. The FETs M1-M3 are controlled by wires K1-K3, and these K wires connect directly to the multi-phase integrator output. The FET resistance characteristic is very non-linear. So once the K value is above a certain minimum the resistance no longer decreases, and when below a certain maximum, no longer increased. Hence the noise of ‘out of range’ integrators is very much reduced.

Example with an Automatic Gain Control Loop

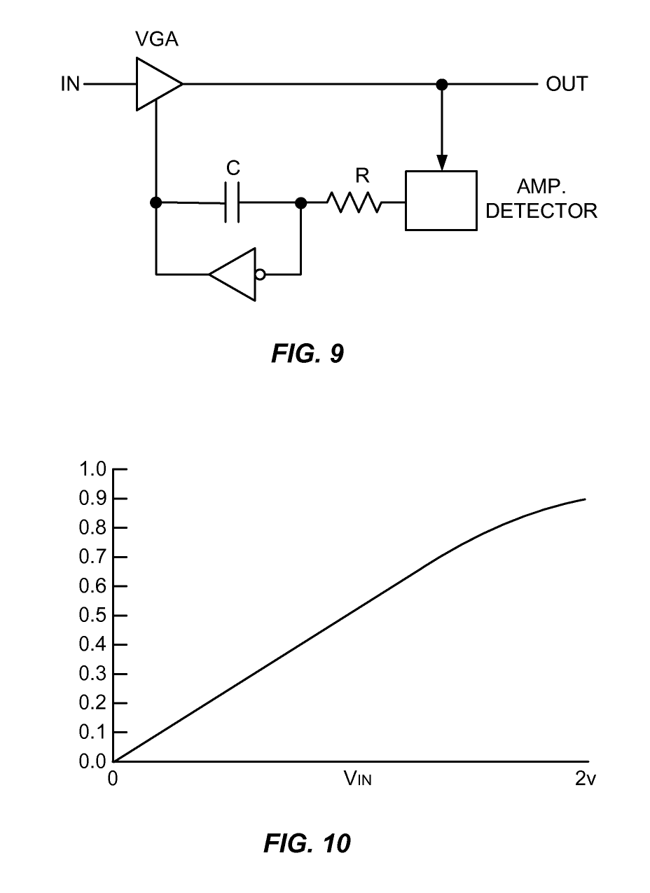

FIG. 9 is the AGC control loop. The amplitude detector (“amp detector”) measures the output amplitude and drives the integrator. The lower input port of the variable gain amplifier (“VGA”) controls the gain. Therefore, if the amplitude detector has insufficient input, the output is low and the integrator ramps up to increase the signal. In one embodiment, the transfer characteristic of the VGA is not the ideal logarithmic response, but for example, is somewhat linear as in FIG. 10. If the AGC has a logarithmic response, the settling time to amplitude change remains the same, and the dynamics (overshoot etc) remain the same.

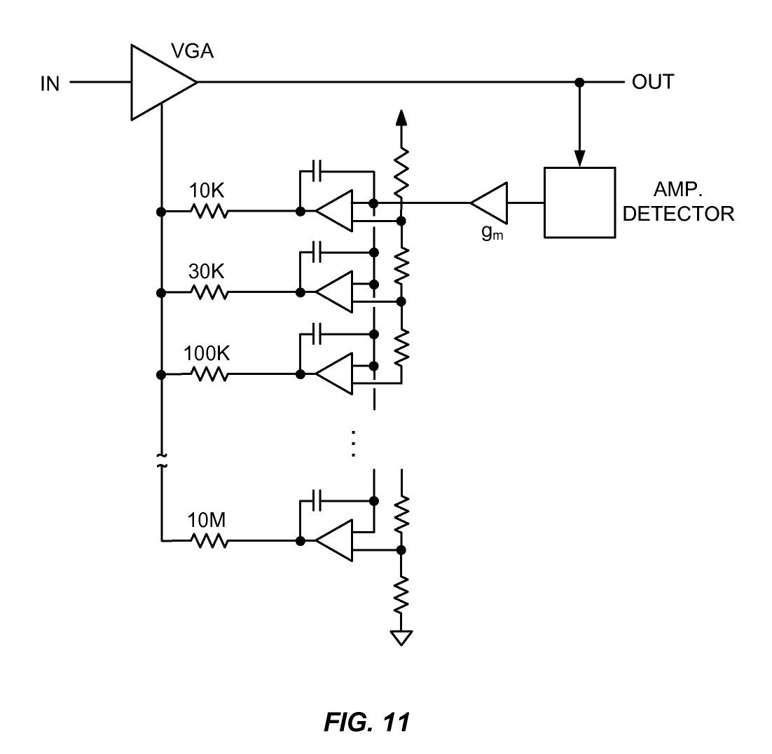

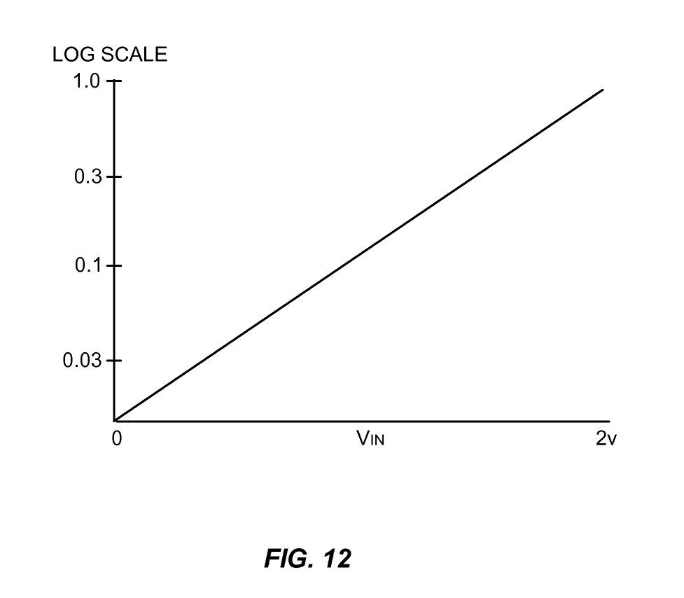

One embodiment is shown in FIG. 11. The multiple integrators connect to the common output of the ‘gm’ block which itself connects to the amplitude detector. The outputs of the integrators all add together to make the VGA control input voltage. But those resistors are far from all equal. The values are constructed such that an approximately logarithmic response is created as shown on FIG. 12.

### CONCLUSION

Multiple integrators in a control loop reduce noise in the stable state. In one embodiment, the open loop gain characteristic of the loop is tailored.

We claim:

1. An apparatus, comprising:
a control loop including:
a plurality of integrators connected in parallel and having a collective input range, the collective input range divided among different input ranges of different integrators of the plurality of integrators.

2. The apparatus of claim 1,
wherein the control loop includes:
an aggregator of outputs of the plurality of integrators; and
a control element responsive to the aggregator, the control element controlling the plurality of integrators.

3. The apparatus of claim 1, wherein the plurality of integrators are connected in parallel electrically, and
wherein the control loop is a phase lock loop including:
a voltage controlled oscillator responsive to the plurality of integrators;
a phase or frequency detector responsive to output of the voltage controlled oscillator, the phase or frequency detector sending a feedback signal toward input of the plurality of integrators.

4. The apparatus of claim 3, wherein the voltage controlled oscillator includes a series connected loop of amplifiers and adjustable resistors.

5. The apparatus of claim 3, wherein the voltage controlled oscillator includes a series connected loop of amplifiers and adjustable resistors, wherein the adjustable resistors include a parallel combination of adjustable resistors.

6. The apparatus of claim 3, wherein the voltage controlled oscillator includes a series connected loop of amplifiers and adjustable resistors, wherein the adjustable resistors are controlled by different outputs of the different integrators of the plurality of integrators.

7. The apparatus of claim 3,
wherein the control loop includes:
a transconductance element responsive to output of the phase or frequency detector, the plurality of integrators responsive to output of the transconductance element.

8. The apparatus of claim 1, wherein the plurality of integrators are connected in parallel electrically, and
wherein the control loop is an automatic gain control loop including:
a variable gain amplifier responsive to a feedback signal from the plurality of integrators;
an amplitude detector responsive to output of the variable gain amplifier, the amplitude detector sending amplitude detector output toward the input of the plurality of integrators.

9. The apparatus of claim 8, wherein the variable gain amplifier has a linear transfer characteristic.

10. The apparatus of claim 8, wherein the variable gain amplifier has a logarithmic transfer characteristic.

11. The apparatus of claim 8, wherein differently valued resistances are in series between (i) the different outputs of the different integrators of the plurality of integrators and (ii) the variable gain amplifier.

12. The apparatus of claim 1, further comprising:
a series of resistances between a high voltage reference and a low voltage reference, wherein different points along the series of resistances provide different voltage references to noninverting inputs of the different integrators of the plurality of integrators.

13. An apparatus, comprising:
a control loop means including:
a plurality of integrator means connected in parallel and having a collective input range, the collective input range divided among different input ranges of different integrator means of the plurality of integrator means.

14. The apparatus of claim 13, further comprising:
a series of resistance means between a high voltage reference and a low voltage reference, wherein different points along the series of resistance means provide different voltage references to noninverting inputs of the different integrator means of the plurality of integrator means.

15. A control loop method, comprising:
responsive to input voltage received by a plurality of integrators connected in parallel, changing an integrator among the plurality of integrators and such that other integrators in the plurality of integrators are inactive.

16. The method of claim 15, comprising:
providing different voltage references to noninverting inputs of different integrators in the plurality of integrators.

17. The method of claim 15, comprising:
the plurality of integrators assisting in phase lock loop processing.

18. The method of claim 17, comprising:
different integrators in the plurality of integrators controlling different variable resistances in a voltage controlled oscillator that assists in the phase lock loop processing.

19. The method of claim 15, comprising:
the plurality of integrators assisting in automatic gain control processing.

20. The method of claim 15, wherein the automatic gain control processing has a logarithmic transfer characteristic.
